(19) United States
(12) Patent Application Publication
(10) Pub. No.: US 2008/0258827 A1
(43) Pub. Date: Oct. 23, 2008

(54) RADIO FREQUENCY VOLTAGE CONTROLLED OSCILLATORS

(75) Inventor: Ming-Da Tsai, Miaoli Hsien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/737,358

(22) Filed: Apr. 19, 2007

(51) Int. Cl. H03B 5/12

(52) U.S. Cl. 331/117 R; 331/108 R

(57) ABSTRACT

A radio frequency voltage controlled oscillator and method for designing it are provided. The RF VCO comprises a differential oscillator and a cascoded current source. The cascoded current source substantially provides a constant current bias to the differential oscillator. A first biased transistor in the cascoded current source is connected to the differential oscillator. A second biased transistor is cascoded to the first biased transistor. A low pass filter is cascoded between the first second biased transistors.

### BACKGROUND OF THE INVENTION

1. Field of the Invention

The invention generally relates to radio frequency (RF) voltage controlled oscillators (VCO) and in particular to VCOs with reduced phase noise.

2. Description of the Related Art

RF communications such as cellular phone applications rely on analog circuits to generate various channel frequencies. Thus, voltage controlled oscillators (VCO) have become important elements of RF communication devices, such as transmitters, where VCOs are used as master oscillators, and receivers, where VCOs are used as local oscillators.

One of the major obstacles to full integration of VCOs is the high phase noise level generated when VCOs are embedded in a frequency synthesizer. Phase noise is rapid, short-term, random fluctuation in the phase of a wave, caused by time domain instabilities and found mostly in active elements used in VCOs. This low frequency noise signal source is often referred to as flicker noise, or noise, in bipolar and Metal Oxide Semiconductor (MOS) transistors.

In comparison with those biased by constant voltage, VCOs biased by constant current are superior to supply or ground common-mode fluctuation, insensitive to process corner variation, and capable of higher output voltage swing. The noise in the active devices of current sources, nevertheless, can be up-converted into an LC tank of a VCO, thereby aggravating the phase noise. To prevent the up-conversion of the noise, various active and/or passive devices are used.

FIG. 1 is a circuit diagram of a conventional RF VCO, in which a biased bipolar transistor Bd is employed as a constant tail current source to bias a differential oscillator. Bipolar transistors are known to have little noise. Even though the noise of bipolar transistor Bd in FIG. 1 is up-converted into the differential oscillator, its effects on the phase noise of the VCO may be negligible. The manufacturing of bipolar transistors together with CMOS transistors is, however, generally more complex and costly than that of only CMOS transistors.

FIG. 2 is a circuit diagram of another conventional RF VCO. Referring to FIG. 2, a low pass filter, including an inductor Ld and a capacitor Cd, is interposed between a differential oscillator and a current source, such that the low pass filter filters the noise from the drain of the current source. The inductor Ld or the capacitor Cd must be large in order to effectively drain the noise to ground, so the implementation of the inductor or capacitor is impractical.

### BRIEF SUMMARY

A radio frequency voltage controlled oscillator is provided, comprising a differential oscillator and a cascoded current source. The cascoded current source substantially provides a constant current bias to the differential oscillator. A first biased transistor in the cascoded current source is connected to the differential oscillator. A second biased transistor is cascoded to the first biased transistor. A low pass filter is cascoded between the first second biased transistors.

A method of designing a radio frequency voltage controlled oscillator is provided. A differential oscillator and a cascoded current source are arranged, such that the cascoded current source substantially provides a current bias required to drive the differential oscillator. The cascoded current source comprises two biased active devices and a low pass filter. One of the two biased active devices is cascoded to the other. The low pass filter is connected between the two biased active devices.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1 and 2 are circuit diagrams of two conventional RF VCOs,

FIG. 3 is a circuit diagram of a RF VCO;

FIG. 4 is a circuit diagram of a RF VCO according to embodiments of the invention;

FIG. 5 is another circuit diagram of a RF VCO;

FIG. 6 illustrates phase noise of the output signal versus the frequency offset from the fundamental frequency f₀ of RF VCOs in FIGS. 3-5, respectively; and

FIG. 7 shows output waves 72, 74 and 76 probed from the outputs of RF VCOs in FIGS. 3-5; and

FIGS. 8 and 9 are circuit diagrams of other RF VCOs according to embodiments of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

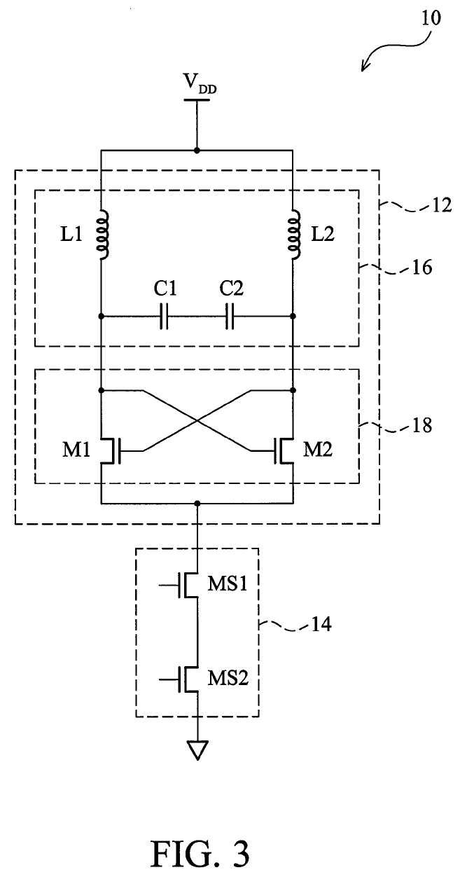

FIG. 3 is a circuit diagram of a RF VCO 10, comprising a differential oscillator 12 and a cascoded tail current source 14. Inductors L1 and L2, and capacitors C1 and C2 form a LC tank 16, substantially determining the fundamental resonant frequency f₀ of RF VCO 10. The connecting node between capacitors C1 and C2 acts as a frequency control terminal of RF VCO 10, voltage on which changes the capacitances of capacitors C1 and C2, thereby determining the fundamental resonant frequency f₀. A cross-coupled transistors pair 18, including MOS transistors M1 and M2, forms a feedback circuit of RF VCO 10, such that the gate of MOS transistor M1 is connected to the drain of MOS transistor M2, and the gate of MOS transistor M2 to the drain of MOS transistor M1. Cascoded tail current source 14 consists of MOS transistors MS1 and MS2, substantially providing a constant current to drive differential oscillator 12.

It is preferred that MOS transistor MS2 have longer and wider channel and MOS transistor MS1 shorter and narrower. Thus, as noise is in positive relationship with current density through a MOS channel, MOS transistor MS2 has relatively insignificant noise. MOS transistor MS1 has more significant noise, which nevertheless will be rejected or alleviated by the cascoded configuration and causes little phase noise to the output wave from differential oscillator 12. Furthermore, less channel length and width also form a small parasitic drain capacitor, lessening the capacitive loading of cascoded tail current source 14 and making it a more ideal current source, with no capacitive loading.

The impedance of MOS transistor MS2 significantly drops at a higher frequency, more particularly due to its channel length and width which form a large parasitic capacitor connected to an ac ground. This large parasitic capacitor effectively connects or shorts the source of MOS transistor MS1 to the ac ground at a higher frequency, and the cascoded configuration in FIG. 3 appears to malfunction since MOS transistor MS2 provides very little effective impedance and cannot boost the overall output impedance seen from differential oscillator 12. Absence of cascoded configuration implies no rejection of significant noise from MOS transistor MS1. In other words, the phase noise of RF VCO 10 at a higher frequency is aggravated.

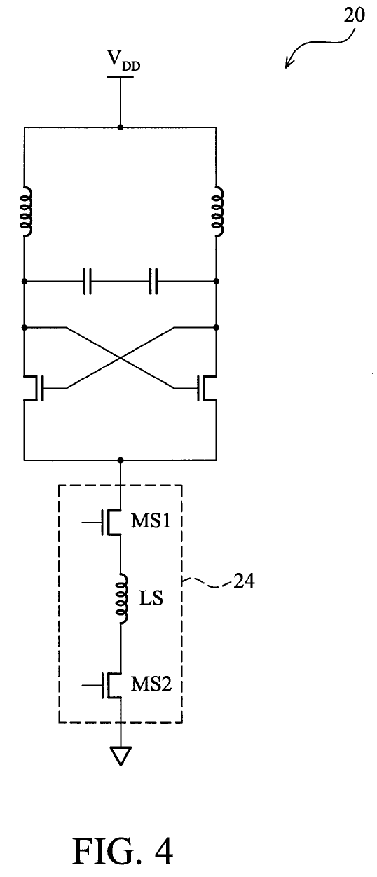

FIG. 4 is a circuit diagram of another RF VCO 20, comprising a differential oscillator 12 and a cascoded tail current source 24. FIG. 4 differs from FIG. 3 only in the presence of an additional inductor LS as a low pass filter connected between cascoded MOS transistors MS1 and MS2. To differentiate the cascoded tail current 14 in FIG. 3, the cascoded tail current source in FIG. 4 is denoted by number 24. At a lower frequency, the impedance of inductor LS, equal to jωL, is negligible, effectively shorting the source of MOS MS1 to the drain of MOS MS2. Thus, the circuit configuration in FIG. 4 is the same as that in FIG. 3 at a lower frequency. Inductor LS plays a key role at a higher frequency, boosting the overall output impedance of cascoded tail current 24. Even though the large parasitic capacitor in MOS transistor MS2 effectively shorts the drain of MOS transistor MS2 to an ac ground at a higher frequency as mentioned, inductor LS, with impedance raises as frequency increases, still significantly stands between the source of MOS transistor MS1 and the ac ground. The overall output impedance of cascoded tail current source 24 is gₘr₀(jωL), where gₘ and r₀ are properties inherent to MOS transistor MS1 and L is the inductance of inductor LS. Irrespective of the condition at a higher or lower frequency, the noise from MOS transistor MS1 is rejected or alleviated by the cascoded configuration effectively contributed by inductor LS or MOS transistor MS2. In conclusion, RF VCO 20 in FIG. 4 is more immune to the noise from MOS transistor MS1 than RF VCO 10 in FIG. 3.

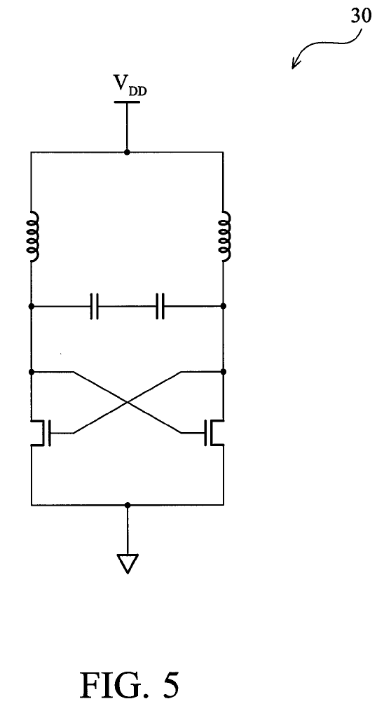

FIG. 5 is a circuit diagram of a voltage-biased RF VCO 30. Unlike the current-biased RF VCOs 10 and 20 in FIGS. 3 and 4, RF VCO 30 in FIG. 5 lacks a tail current source and has only differential oscillator 12 directly powered by power rails Vdd and ground.

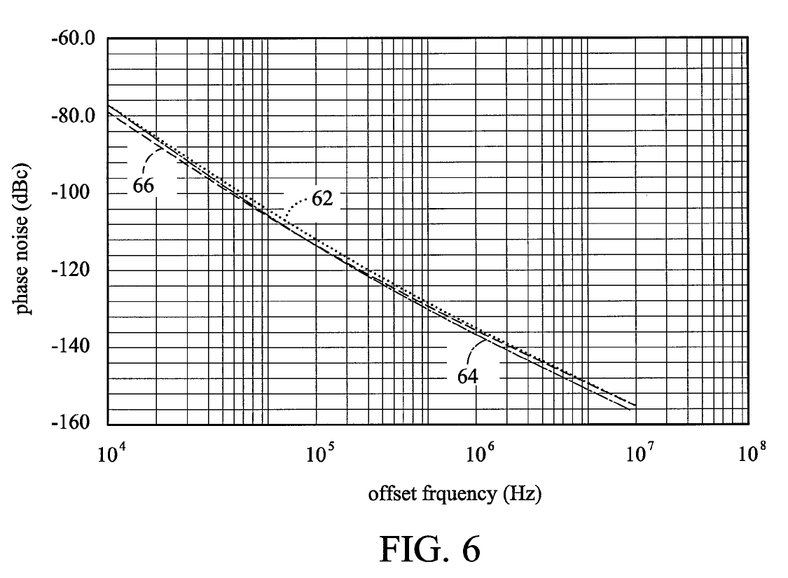

FIG. 6 plots 62, 64 and 66, illustrating the phase noise of the output signal versus the frequency offset from the fundamental frequency f₀ of RF VCOs 10, 20 and 30, respectively. As can be seen, the phase noises of current-biased RF VCOs 10 and 20 at 10 KHz offset frequency (a lower offset frequency) are substantially the same, but higher than that of voltage-biased RF VCO 30 because of the noise of MOS transistor MS2 in current-biased RF VCOs 10 and 20. At a higher offset frequency, such as 20 MHz, plots 62 and 64 separate, and the phase noise of current-biased RF VCO 20 is improved about 3 dB compared with that of current-biased RF VCO 10, which lacks inductor LS.

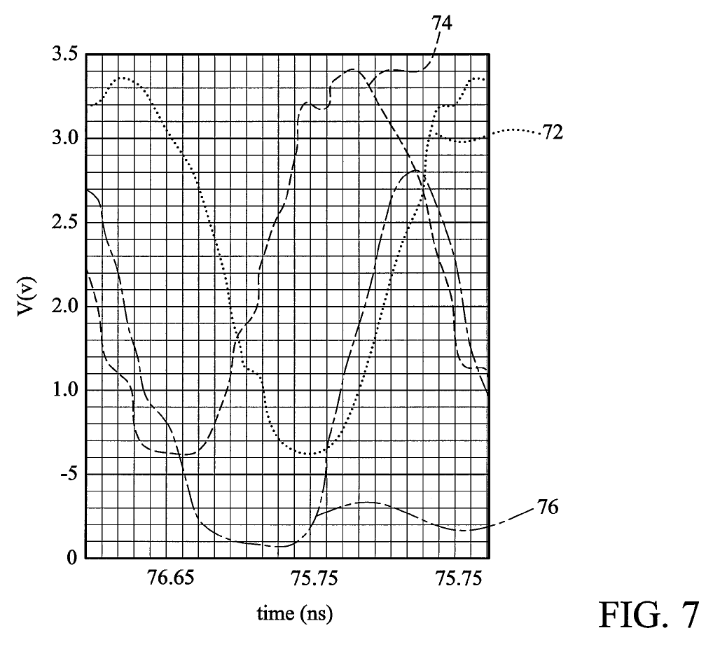

FIG. 7 shows output waves 72, 74 and 76 probed from the outputs of RF VCOs 10, 20 and 30. As can be seen, wave 74, corresponding to current-biased RF VCO 20 with inductor LS, has an output voltage swing of about 2.8, the largest of the 3 waves 72, 74 and 76 in FIG. 7.

As shown in FIG. 4, it is critical for inductor LS to be located between MOS transistors MS1 and MS2. Otherwise, locating an inductor between the source of MOS transistor MS2 and ground barely affects the output impedance of the cascoded tail current source at a higher frequency because of the large grounded parasitic capacitor of intervening MOS transistor MS2, which effectively shorts one terminal of the inductor to ground. An inductor between the drain of MOS transistor MS1 and differential oscillator 12 does not experience the output impedance boost caused by the gain stage of MOS transistor MS1 at a higher frequency. To have the same impedance as that between MOS transistors MS1 and MS2 at a higher frequency, an inductor connected to the drain of MOS transistor MS1 requires much higher inductance, occupying more silicon surface. Thus, it is preferred, economically and practically, for inductor LS to be connected in serial between MOS transistors MS1 and MS2.

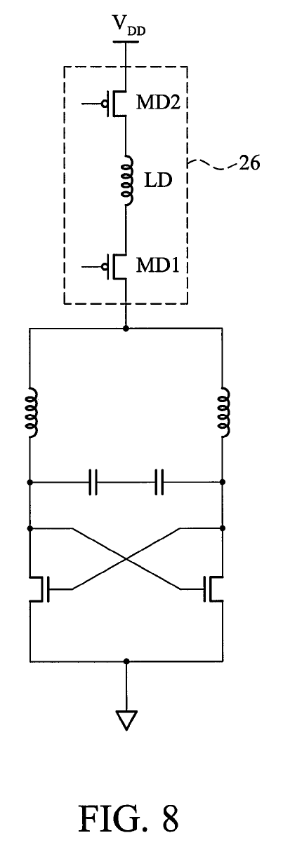

Each of both cascoded current sources 14 and 24 in FIGS. 3 and 4 is connected between ground and a differential oscillator. The invention is not limited thereto, however. Embodiments of the invention may have a current source connected between VDD power line and a differential oscillator, as shown in FIG. 8 where cascoded current source 26 has cascoded MOS transistors MD1 and MD2, and an inductor LD therebetween. It is preferred that MOS transistor MD2 has a longer and wider channel than MOS transistor MD1.

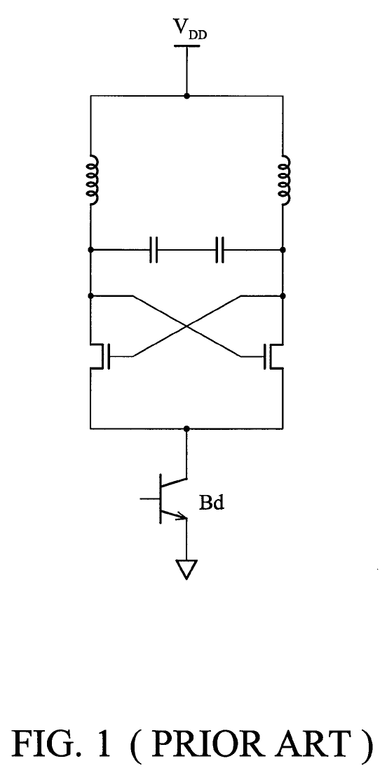

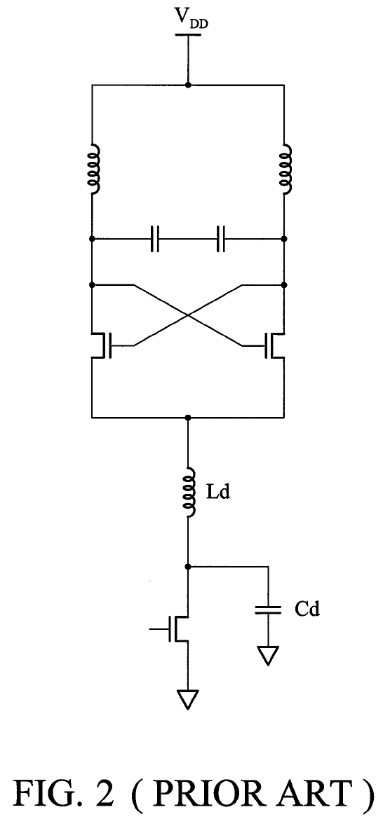

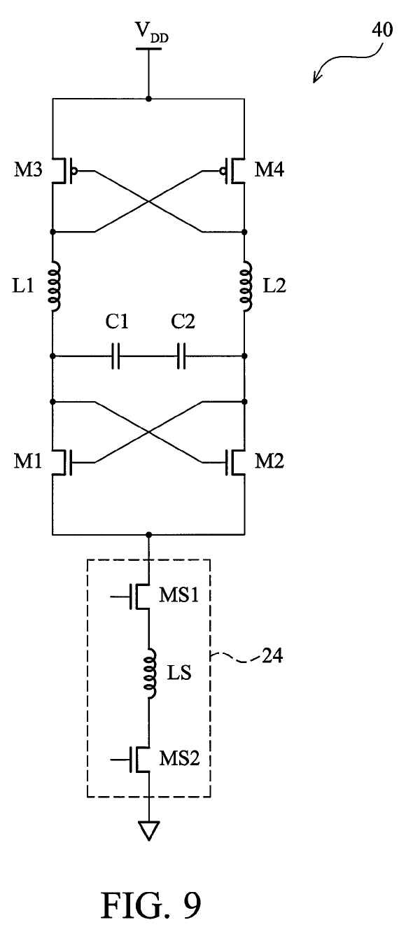

A differential oscillator in an embodiment of the invention may be different from those disclosed in FIGS. 1-5 and 8. FIG. 9 exemplifies another RF VCO 40 with an alternative differential oscillator, which has a cross-coupled transistor pair (including MOS transistors M3 and M4) connected to inductors L1 and L2 and VDD power line. Each of capacitors C1 and C2 may comprise a varactor with voltage-controllable capacitance for frequency tuning.

As the phase noise of RF VCO 20 is insensitive to the inductance variation of inductor LS, it is unimportant to have an inductor with a highly-accurate inductance, such that a multi-turn or 3D inductor is acceptable. Furthermore, the metal line width used in inductor LS can be smaller since substantially constant current flows therethrough.

While the invention has been described by way of examples and in terms of preferred embodiment, it is to be understood that the invention is not limited thereto. To the contrary, it is intended to cover various modifications and similar arrangements (as would be apparent to those skilled in the art). Thus, the scope of the appended claims should be accorded the broadest interpretation so as to encompass all such modifications and similar arrangements.

What is claimed is:

1. A radio frequency voltage controlled oscillator, comprising:
a differential oscillator; and
a cascoded current source substantially providing a constant current bias to the differential oscillator; comprising:
a first biased transistor connected to the differential oscillator;
a second biased transistor cascoded to the first biased transistor; and
a low pass filter cascoded between the first second biased transistors.

2. The radio frequency voltage controlled oscillator of claim 1, wherein the differential oscillator comprises:
a LC tank; and
a pair of cross-coupled MOS transistors, a drain of each being in communication with a gate of the other, and a source of each being in communication with a source of the other.

3. The radio frequency voltage controlled oscillator of claim 1, wherein the first and second biased transistors are MOS transistors.

4. The radio frequency voltage controlled oscillator of claim 3, wherein the first biased transistor has a shorter and narrower channel than the second biased transistor.

5. The radio frequency voltage controlled oscillator of claim 1, wherein the low pass filter is an inductor.

6. The radio frequency voltage controlled oscillator of claim 1, wherein the differential oscillator comprises at least two varactors for frequency tuning.

7. A method of designing a radio frequency voltage controlled oscillator, comprising:
arranging a differential oscillator and a cascoded current source, such that the cascoded current source substantially provides a current bias required to drive the differential oscillator;
wherein the cascoded current source comprises:
two biased active devices, one being cascoded to the other; and
a low pass filter connected between the two biased active devices.

8. The method of claim 7, wherein the cascoded current source is connected between a high power line and the differential oscillator, and the differential oscillator is connected to a low power line.

9. The method of claim 7, wherein the cascoded current source is connected between a low power line and the differential oscillator, and the differential oscillator is connected to a high power line.

10. The method of claim 7, wherein the differential oscillator comprises:
a LC tank; and
a pair of cross-coupled MOS transistors, a drain of each being in communication with a gate of the other, and a source of each being in communication with a source of the other.

11. The method of claim 10, wherein the LC tank comprises a pair of varactors for frequency tuning.

12. The method of claim 7, wherein the biased active devices are MOS transistors.

13. The method of claim 12, wherein one of the biased active devices is connected to the differential oscillator and has a shorter and narrower channel than the other biased active device.

14. The method of claim 7, wherein the low pass filter is an inductor.

15. The method of claim 14, wherein the inductor is multi-turn or 3-D inductor.
